(19) United States
(12) Patent Application Publication
(10) Pub. No.: US 2019/0020088 A1
(43) Pub. Date: Jan. 17, 2019

(54) MICROWAVE DIGITAL PHASE SHIFTERS

(71) Applicant: Nuvotronics, Inc., Radford, VA (US)

(72) Inventors: Steven E Huettner, Tucson, AZ (US); Gayle Fran Collins, Raleigh, NC (US)

(21) Appl. No.: 15/622,185

(22) Filed: Jun. 14, 2017

Related U.S. Application Data
(60) Provisional application No. 62/350,411, filed on Jun. 15, 2016.

(51) Int. Cl. H01P 1/185; H01P 1/15; H03K 17/693; H03K 17/687

(52) U.S. Cl. CPC H01P 1/185; H03K 17/6871; H03K 17/693; H01P 1/15

(57) ABSTRACT

A microwave digital phase shifter, comprising input and output ports having a reference path and a delay path disposed in parallel therebetween, the reference path including a switch element shunted to ground and the delay path including at least one switch element shunted to ground and including a transmission line to provide a phase difference between the reference path and the delay path.

### RELATED APPLICATIONS

This application claims the benefit of priority of U.S. Provisional Application No. 62/350,411, filed on Jun. 15, 2016, the entire contents of which application(s) are incorporated herein by reference.

### GOVERNMENT LICENSE RIGHTS

This invention was made with government support under Contract No. N00024-16-C-4035 awarded by U.S. Navy (Naval Sea Systems Command). The government has certain rights in the invention.

### FIELD OF THE INVENTION

The present invention relates generally to the field of microwave digital phase shifters, more particularly but not exclusively to a 180 or 90 degree bit with low loss and wide bandwidth.

### BACKGROUND OF THE INVENTION

A current need exists for better phase shifter bits for RF applications. For passive electronically scanned arrays (ESA), low-loss phase bits are extremely important, and if a passive ESA is to serve as a radar, high-power handling becomes an additional critical requirement. Moreover, passive ESAs offer reduced functionality compared to active ESAs, therefore a phase shifter used in a passive ESA should also be low in cost to offer an attractive solution.

In addition, a problem encountered in the real world with ring hybrid phase shifters is that there is no switchable termination that can provide perfect open and short circuits to the coupled ports. For any termination there will be parasitic series inductance (i.e. a bond wire); the on-state of the device will have some small resistance; and, there will be parasitic capacitance in the off state. If one accounts for the wire-bond, the reactance of the wire-bond would be suffered twice in reflection, which makes the design particularly sensitive to the as-built geometry of the bond-wire. Thus, the placement of a diode can become critical to performance, as misalignment can increase the length of the wire-bond. In the case of monolithic microwave integrated circuits, there is no actual wire-bond inductance, but there is series inductance associated with the drain and source fingers. Thus, there is a need in the art for improved ring hybrid phase shifters, especially for an improved network that can absorb switch element parasitics and provide better performance over a broader band.

### SUMMARY OF THE INVENTION

In one of its aspects, the present invention applies to phase shifters using switch elements, such as MESFETs, PIN diodes, HEMTs, PIN diodes, phase change, and metal-insulator transition devices. More particularly the present invention relates to phase shifters where flat-phase with frequency is provided, as opposed to true-time delay phase shifting.

High-power handling may be improved when an “all shunt” architecture is provided, especially in the case of phase shifters using FET switch elements. In this case, RF signals do not pass through switch FETs in series with device biased into the on-state, but are routed past them in shunt when the device is biased into the off-state. High power handling is particularly improved when GaN HEMT technology may be used due to its greatly enhanced breakdown voltage compared to GaAs technologies. A breakdown voltage of 80 volts, for example, allows 16-watt waveform in a fifty-ohm system before clipping occurs.

Accordingly, in one of its aspects the present invention provides a microwave digital phase shifter comprising input and output ports and having a reference path and a delay path disposed in parallel therebetween. The reference path may include a switch element shunted to ground. The delay path may include at least one switch element shunted to ground and may include a transmission line to provide a phase difference between the reference path and the delay path. The switch elements of the reference and delay paths may include, for example, FETs or PIN diodes. In addition, the reference path may include a shunt resonator to provide a resonant structure in parallel with the capacitance of the switch element of the reference path. Likewise, the delay path may include shunt resonators to provide respective resonant structures in parallel with the capacitance of each of the at least one switch elements of the delay path.

### BRIEF DESCRIPTION OF THE DRAWINGS

The foregoing summary and the following detailed description of exemplary embodiments of the present invention may be further understood when read in conjunction with the appended drawings, in which:

FIG. 1 schematically illustrates an exemplary configuration of a single pole, double throw switch in accordance with the present invention;

FIG. 2 schematically illustrates a further exemplary configuration of a single pole, double throw switch in accordance with the present invention;

FIG. 3 schematically illustrates an exemplary configuration of an asymmetric single pole, double throw switch in accordance with the present invention;

FIG. 4 schematically illustrates an exemplary configuration of a phase shifter architecture in accordance with the present invention combining two back-to-back switches of FIG. 3;

FIG. 5A schematically illustrates an exemplary configuration of a phase shifter architecture according to FIG. 4 in which redundant components are removed;

FIG. 5B schematically illustrates an exemplary configuration of a phase shifter architecture in accordance with the present invention similar to that of FIG. 5A but including two switch FETs in each of the reference and delay paths;

FIG. 5C schematically illustrates an exemplary configuration of a phase shifter architecture in accordance with the present invention similar to that of FIG. 5B but having capacitors at each of the input and output ports in lieu of inductors in the reference and delay paths;

FIG. 6 illustrates the predicted phase shift for a 22.5 degree implementation of the phase shifter of FIG. 5A;

FIG. 7 illustrates the predicted phase shift for a 45 degree implementation of the phase shifter of FIG. 5A;

FIG. 8 illustrates the predicted phase shift for a 90 degree implementation of the phase shifter of FIG. 5A;

FIG. 9 illustrates the predicted phase shift for a 180 degree implementation of the phase shifter of FIG. 5A;

FIG. 10 schematically illustrates an exemplary physical layout of a 90 degree implementation of the phase shifter of FIG. 5A using PIN diodes for the switch elements;

FIGS. 11A, 11B illustrate the measured response of the phase shifter of FIG. 10;

FIG. 12A schematically illustrates an exemplary configuration of a ring hybrid phase shifter in accordance with the present invention;

FIG. 12B schematically illustrates an exemplary configuration of a hybrid 180 degree phase shifter in accordance with the present invention similar to that of FIG. 12A but having capacitors at each of the input and output ports in lieu of inductors in the reference and delay paths;

FIG. 13 schematically illustrates a two-port shunt switch element model of a diode;

FIG. 14 illustrates the predicted return losses and transmission losses of the ring hybrid phase shifter of FIG. 12A;

FIG. 15 schematically illustrates the predicted phase shift of the ring hybrid phase shifter of FIG. 12A;

FIG. 16A schematically illustrates an exemplary configuration of a two ring, wideband hybrid phase shifter in accordance with the present invention;

FIG. 16B schematically illustrates an exemplary configuration of a two ring, wideband hybrid 180 degree phase shifter in accordance with the present invention similar to that of FIG. 16A but having capacitors at each of the input and output ports in lieu of inductors in the reference and delay paths;

FIG. 17 illustrates the predicted return loss and transmission loss of the two ring, wideband hybrid phase shifter of FIG. 16A;

FIG. 18 illustrates the predicted phase shift response of the two ring, wideband hybrid phase shifter of FIG. 16A;

FIG. 19 schematically illustrates an exemplary physical layout of the two ring, wideband hybrid phase shifter of FIG. 16A using PIN diodes as switch elements; and

FIGS. 20A, 20B illustrate the measured performance of the two ring, wideband hybrid phase shifter of FIG. 19.

### DETAILED DESCRIPTION OF THE INVENTION

In one of its aspects, the present invention relates to a new form of switched line phase shifter with reduced complexity compared to other efforts. Exemplary configurations of phase shifters in accordance with the present invention may include back-to-back switch elements while other exemplary configurations may include hybrid rings. Phase shifters of the present invention may include switch arms that employ only shunt elements to achieve high-power handling. As few as two switch devices may be used. The phase shifters can be used for a wide range of phase shift needs, such as 180, 90, 45 or 22.5 degree bit, in a multi-bit digital phase shifter.

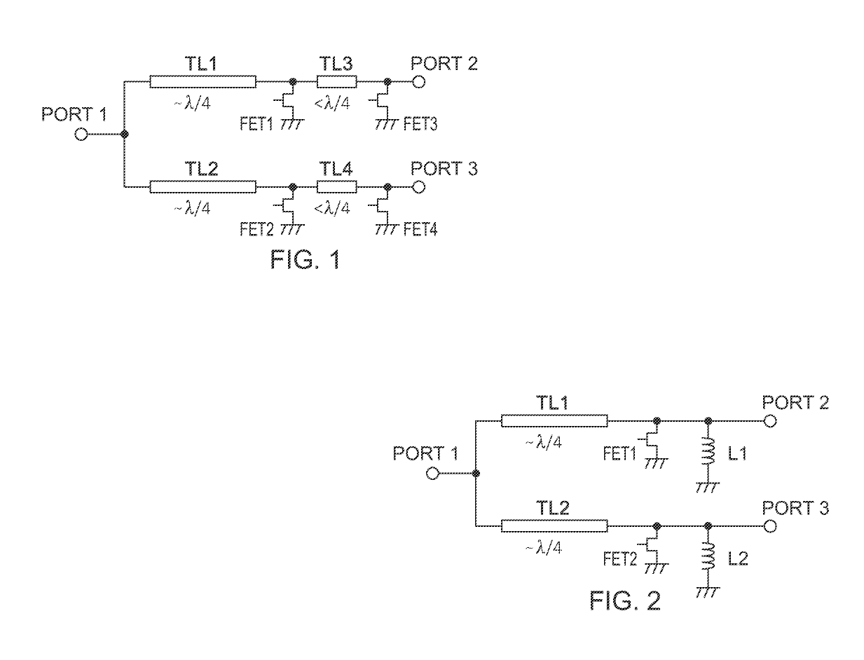

Turning first to back-to-back switch configurations, FIG. 1 schematically illustrates a type of single pole, double throw (SPDT) switch in which all the switch elements FET1-FET4 operate as shunts. While the switch elements are illustrated as FETs other switch types may be used, such as PIN diodes, MEMS switches, etc. The switch elements FET1-FET4 may be operated in pairs, so that FET1 and FET3 are controlled together and FET2 and FET4 are controlled together. The arm in which a FET pair (e.g., FET1, FET3) is in the on-state is referred to as the “isolated arm,” while the arm in which the FET pair (e.g., FET2, FET4) is in the off-state is referred to as the “low-loss arm.” The switch elements FET1-FET4 desirably have low resistance in the on-state to shut down the isolated arm. A pair of nearly-quarter-wave lines TL1 and TL2 may be placed at the common port, Port1, to counteract the low impedance of the shunt FETs in the isolated arm, allowing the isolated arm to behave as an open circuit so the isolated arm does not load down the low-loss arm.

Even the best RF FETs or PIN diodes may have capacitance that must be dealt with in switch design; this consideration gets worse as operating frequency is increased. In order to make the low-loss arm impedance matched, a series line TL3, TL4 may be used between each FET pair FET1/FET3, FET2/FET4. By physically separating the switch FETs with a line TL3, TL4 that is less than ¼ wavelength, the capacitance of the FET pairs can be made to cancel out at center frequency, providing a bandpass response. The use of two FETs in each arm also provides double the isolation that one FET would provide, but increases the loss of the switch.

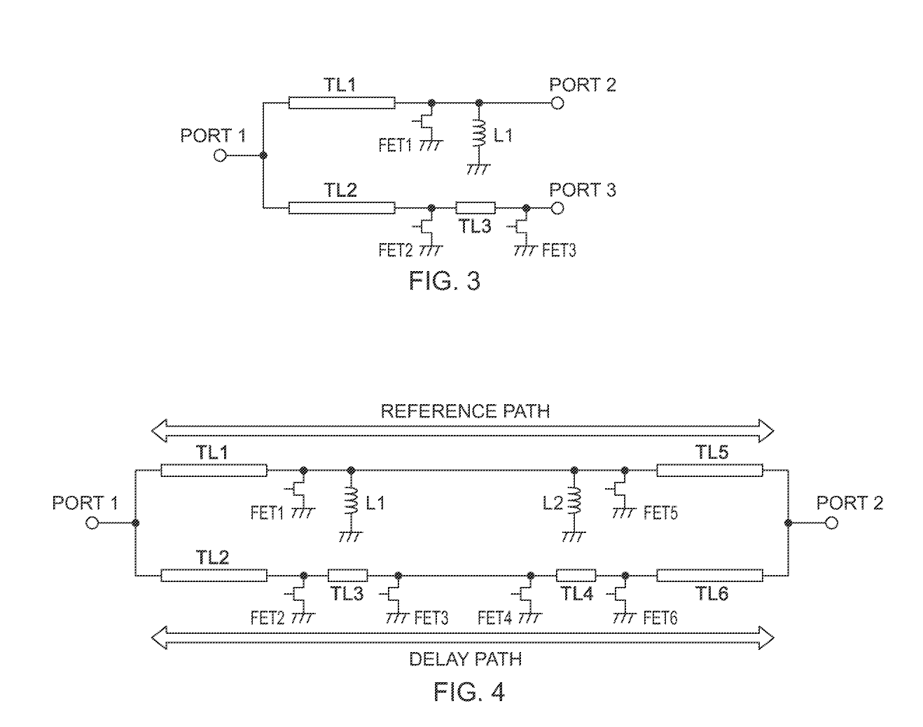

FIG. 2 schematically illustrates a second exemplary SPDT switch in accordance with the present invention. Here, the off-capacitance of each FET (FET1, FET2) is counter-acted by a shunt inductor L1, L2, a form of parallel resonant circuit. Inductor L1 forms a resonant structure with the capacitance of FET1 and inductor L2 forms a resonant structure with the capacitance of FET2, so that the phase shifter is not capacitively loaded when the low-loss path is chosen. Such a switch needs only two FETs or other switch devices, but can use additional devices for increased isolation. The switch also provides a bandpass response.

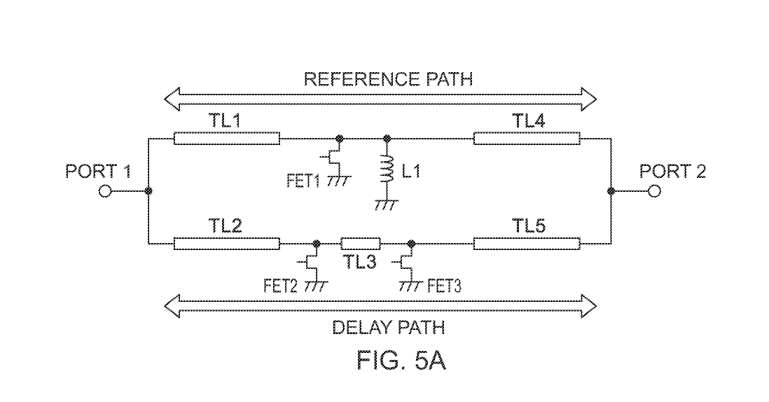

FIG. 3 shows an exemplary asymmetric switch in accordance with the present invention created by combining the upper switch arm from the switch of FIG. 2 with the lower switch arm from the switch of FIG. 1. One characteristic of such a switch is that the transmission characteristics of the two arms in their respective low-loss states are different, in particular, they have different insertion phases. With this design it is possible to create a switch with the top arm (Port1 to Port2) having nearly constant phase difference with respect to the bottom arm (Port1 to Port3) over a useful bandwidth.

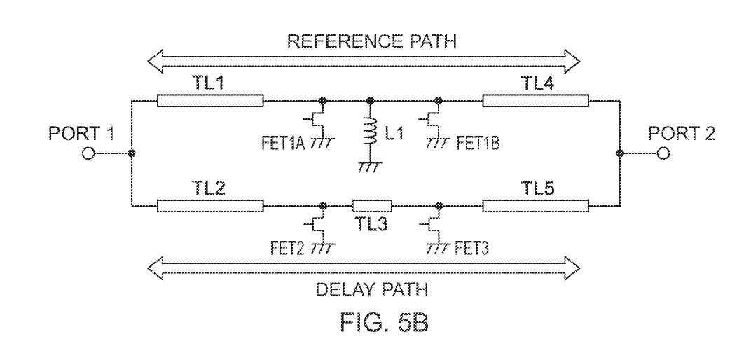

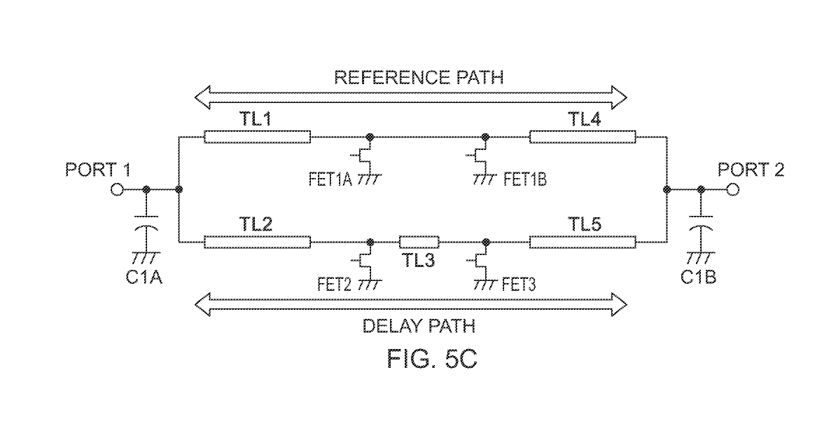

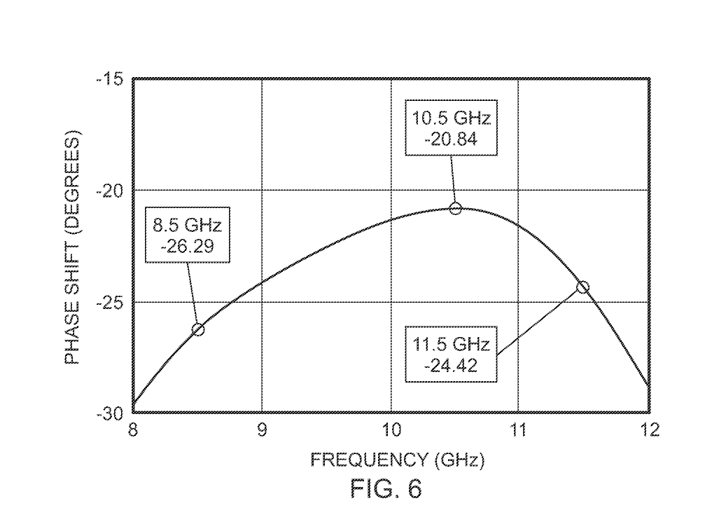

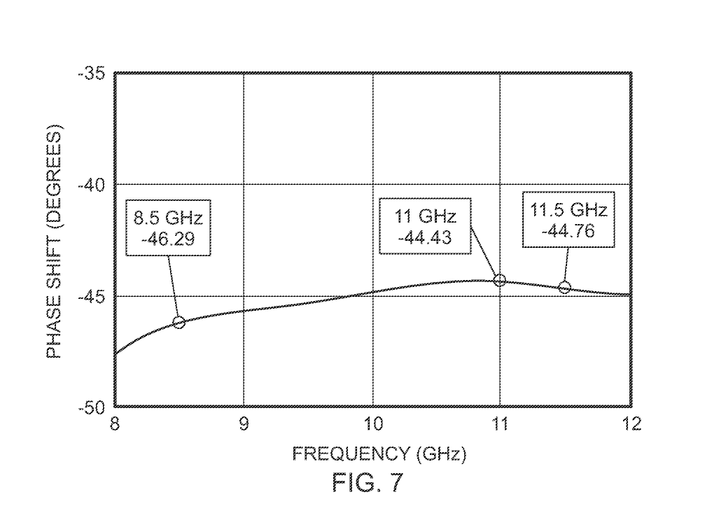

Configuring two of the asymmetric switches of FIG. 3 back-to-back provides a two-port circuit that can act as a phase shifter, with six FETs (FET1-FETE) operating from two control voltages, FIG. 4. FET1 and FET 5 are operated together, while FET2, FET3, FET4 and FETE are operated together. This phase shifter uses an all-shunt architecture for high-power handling. The reference path and delayed paths are denoted. TL1, TL2, TL5 and TL6 are nearly ¼ wavelength. Inductors L1, L2 form shunt resonators for FET1 and FET5, respectively. The phase shifter in FIG. 4 has redundant components which can be eliminated to reduce size and complexity and insertion loss. Because of the back-to-back configuration, the reference and delayed paths of the phase shifter can share the same three FETs. Removing the redundant components, a simplified three-FET digital phase shifter is shown in FIG. 5A.

The phase shifters of FIGS. 5A-5C can be tuned for a wide variety of phase responses using optimization techniques. All of the transmission lines and the inductor provide degrees of freedom, as well as the size of the switch devices. Table 1 shows impedance and length values for 22.5, 45, 90 and 180 bit examples of the switch of FIG. 5A using FETs as switch devices at a center frequency of 10 GHz. There are no exact values for all of the parameters that provides the best response, as different optimization functions can be used to weight different characteristics.

Using the topologies of FIGS. 5B and 5C would result in slightly different values for impedances and lengths of the transmission lines TL1-TL5. In each example, the FET off capacitance was 0.175 fF and the on-resistance was 1.5 ohms for the shifter configuration of FIG. 5A. No other parasitics (such as wire-bond inductance) were considered in the examples.

TABLE 1

| | 22.5-degree bit | | 45-degree bit | | 90-degree bit | | 180-degree bit | |
|---|---|---|---|---|---|---|---|---|
| Transmission | Impedance | Length | Impedance | Length | Impedance | Length | Impedance | Length |
| line | (ohms) | (degrees) | (ohms) | (degrees) | (ohms) | (degrees) | (ohms) | (degrees) |
| TL1, TL4 | 43 | 86 | 44 | 91 | 53 | 89 | 38 | 92 |
| TL2, TL5 | 49 | 111 | 50 | 99 | 62 | 88 | 73 | 94 |
| L1 | 78 | 13 | 100 | 18 | 96 | 39 | 20 | 161 |
| TL3 | 75 | 43 | 88 | 45 | 99 | 38 | 99 | 40 |

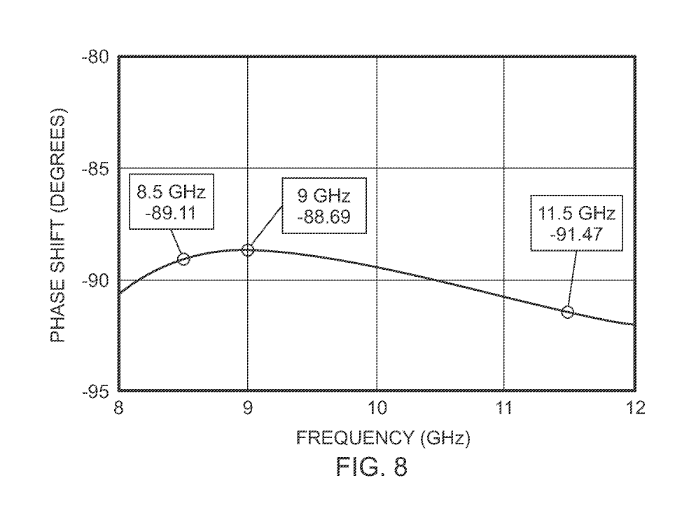

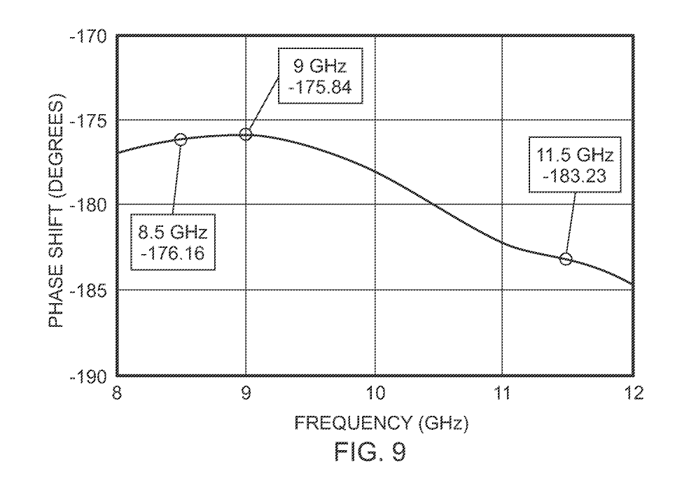

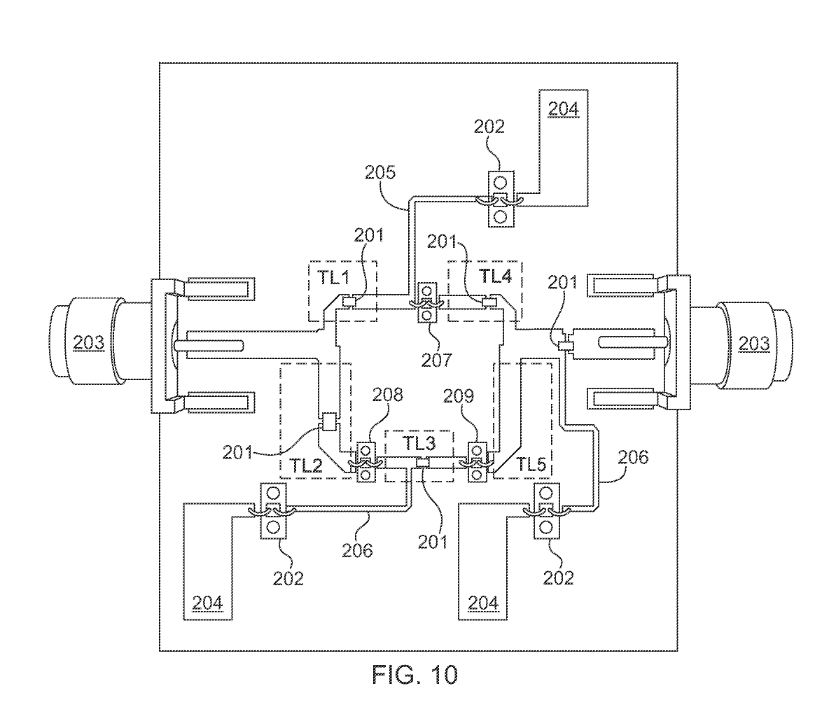

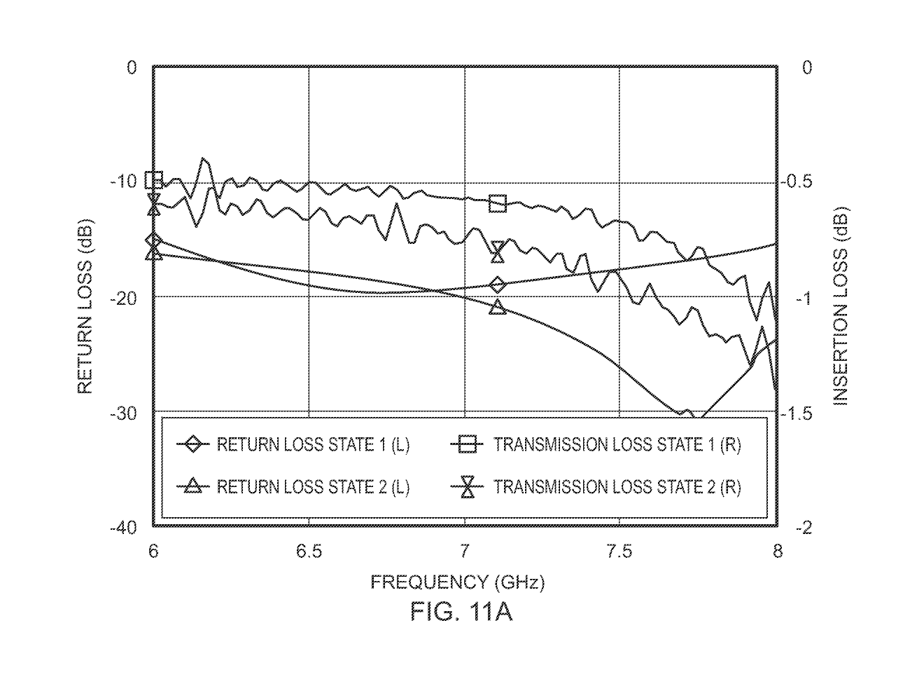

FIGS. 6-9 show the predicted phase shift for the four exemplary phase bits of Table 1 plotted over 40% bandwidth (8 to 12 GHz). Although none of the examples provide a perfect phase shift across the band, the phase errors are manageable in most systems and represent a considerable improvement from the classic switched-line phase shifter. The delay and reference paths of the design of FIG. 5A can be enhanced with well-known circuit tuning elements to further improve the phase flatness with frequency.

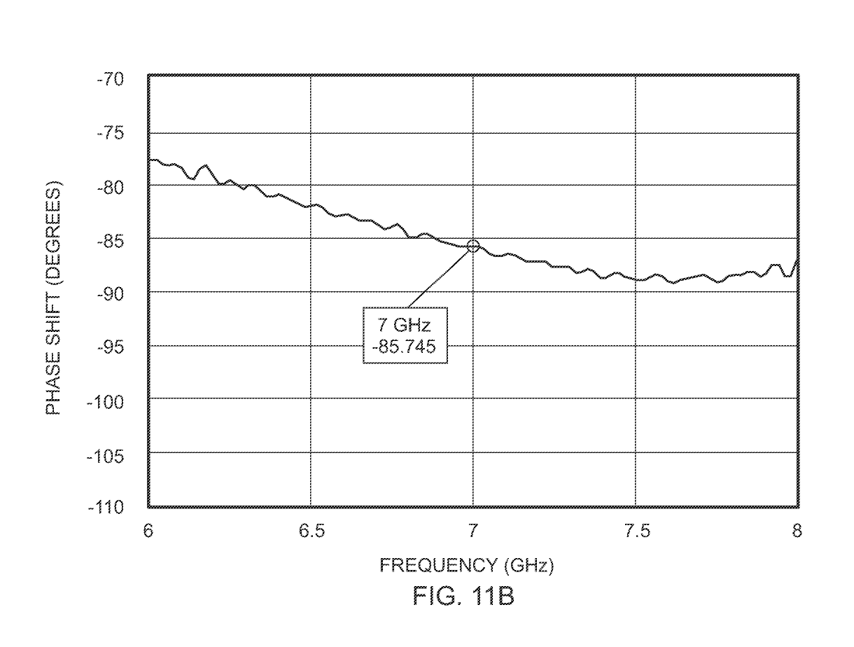

A physical example of the phase shifter that was built based on the design of FIG. 5A is shown in FIG. 10, which is a PIN diode design centered at 7 GHz. The phase shifter of FIG. 10 was realized on a substrate that was 508 microns in thickness with dielectric constant of 2.2 and includes input/output connectors 203. The bias circuits required for PIN diodes 207, 208, 209 have increased the complexity of the structure to include blocking capacitors 201, bypass capacitors 202, and bias stubs 206. In this example, the PIN diodes' off capacitance was approximately 0.175 fF and the on-resistance was ˜1 ohm. Wire-bonds of 400 μm length were absorbed into the design. Although the two lower diodes 208, 209 have separate bias control signal inputs (204), they are driven together during operation. Inductor 205 compensates for the upper PIN diode's_207 off-capacitance, acting as an inductive resonator in the manner of L1 in FIG. 5A. The stubs labeled 206 are merely to bring DC current to diode 208 and diode 209, but can offer additional degrees of freedom in tuning the design.

A table of line widths and their corresponding impedances for the physical example FIG. 10 is provided in Table 2. The electrical lengths cannot be accurately reported as a single number, due to the effects of tee junctions on transmission phase.

TABLE 2

| Segment | Width (microns) | Impedance (ohms) |
|---|---|---|
| TL1 | 1085 | 62 |
| TL2 | 660 | 81 |
| L1 (205) | 600 | 85 |
| TL3 | 250 | 121 |
| TL4 | 1085 | 62 |
| TL5 | 660 | 81 |

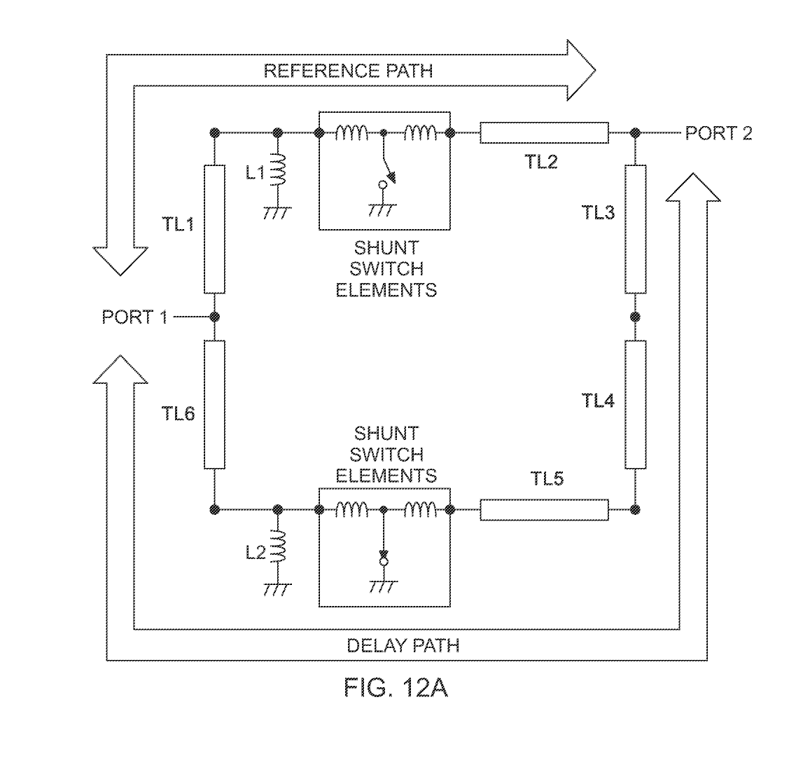

Measured data of the C-band 90-degree PIN diode phase shifter of FIG. 10 is shown in FIGS. 11A, 11B. At band center the loss is 0.6 and 0.75 dB in the two states. Phase shift from 6 to 8 GHz (˜28.5% bandwidth) has just 11 degrees of variation. The performance of this prototype can be improved with a second design iteration, but it serves to provide a physical example of the invention described.

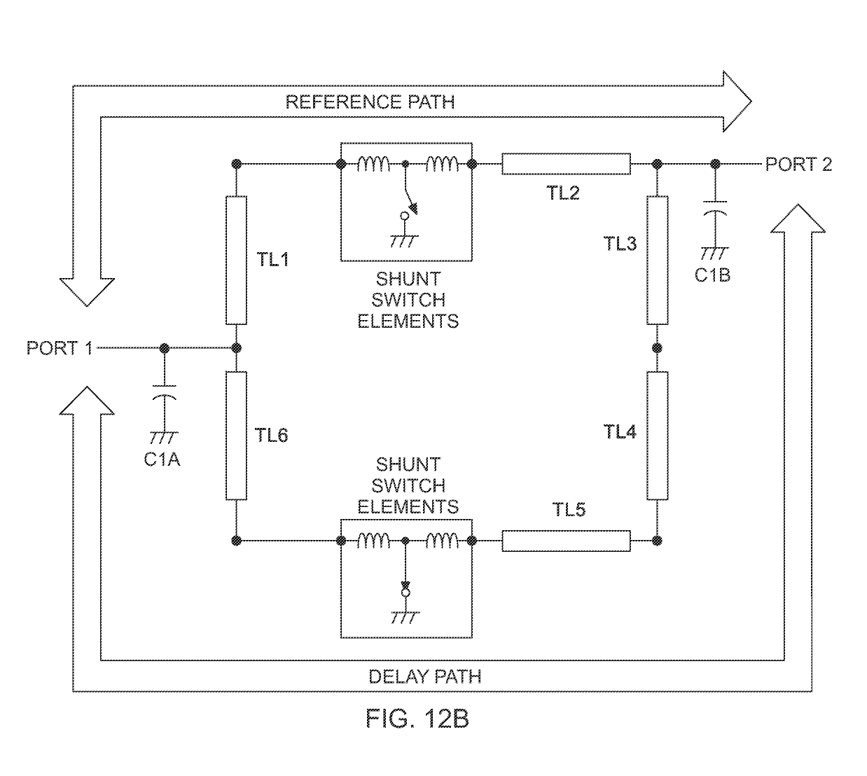

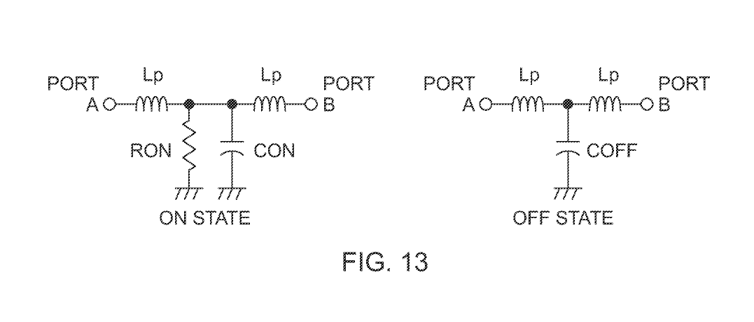

In another of its aspects the present invention provides a ring hybrid phase shifter, which may be configured to provide a 180-degree phase shifter having near-ideal phase and amplitude performance over considerable bandwidth based, as illustrated in FIGS. 12A, 12B.

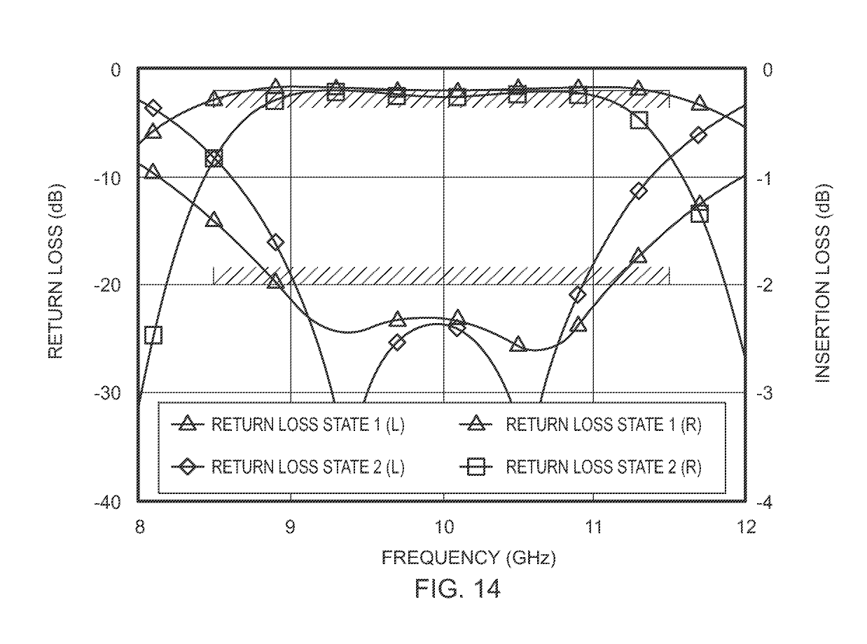

A first feature of interest in the design is the addition of resonators L1, L2 in parallel with the switch devices (“shunt switch elements”) to compensate for switch element parasitic capacitance. The shunt inductors L1, L2 may be high-impedance transmission lines. This first feature can make the response at center frequency nearly ideal, even with considerable parasitic capacitance. A second feature of interest are the additional degrees of freedom in the design. Ordinary hybrid ring couplers use uniform impedance around the ring, at SQRT(2)xZ0 impedance. By permitting the impedance to vary around the ring, more bandwidth can be obtained. In FIGS. 12A, 12B, transmission lines TL1 through TL6 do not need to be 71 ohms in a 50-ohm system. As an additional feature of interest, the phase shifter splits the ring hybrid and incorporates the switch elements inside of the ring rather than externally to the ring. This forms a different class of phase shifter; rather than a reflection phase shifter, the phase shifter of FIGS. 12A, 12B becomes a unique, switched path phase shifter. The path differences are naturally 180 degrees at center frequency, and the degrees of freedom offered by the first and second features allows the phase shift to be nearly flat over wide bandwidths. Also, the phase shifter layout becomes more compact compared to a reflection phase shifter. Further, some of the transmission lines TL1-TL6 may not be exactly one-quarter wavelength. In practice, the transmission lines TL1-TL6 may be reduced to absorb the transmission phase angle of the shunt switch elements described in FIG. 13.

A model for “shunt switch elements” is shown in FIG. 13, showing both “on” and “off” states. In the on-state, the switch element's intrinsic characteristic is that it is a low-value shunt resistance “Ron” which overwhelms the effect of the on capacitance “Con”. In the off state, the switch element's intrinsic characteristic is that it behaves as a shunt capacitance “Coff”. Here, two ports (Port A, Port B) are required, and in the case of a discrete switch element, a pair of wire-bonds connect the switch to the ring. In the case of a FET in a monolithic circuit, parasitic series inductance is present at each port due to the lengths of the FET's fingers, but the parasitic series inductance may be reduced compared to wire-bonds. In FIG. 13, the series inductance is designated “Lp” for parasitic inductance. In addition, minor misalignments of the switch during assembly are better tolerated in the ring hybrid phase shifter of FIGS. 12A, 12B: if one wire-bond is made shorter the other one is made longer, and the total inductance (and transmission phase) is not affected.

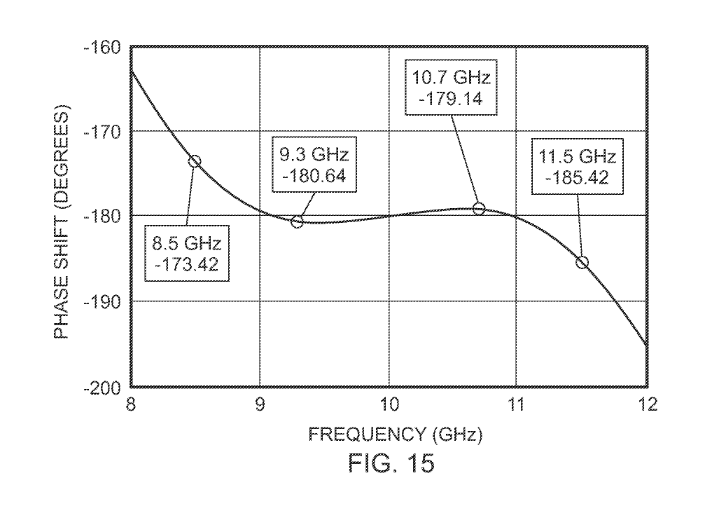

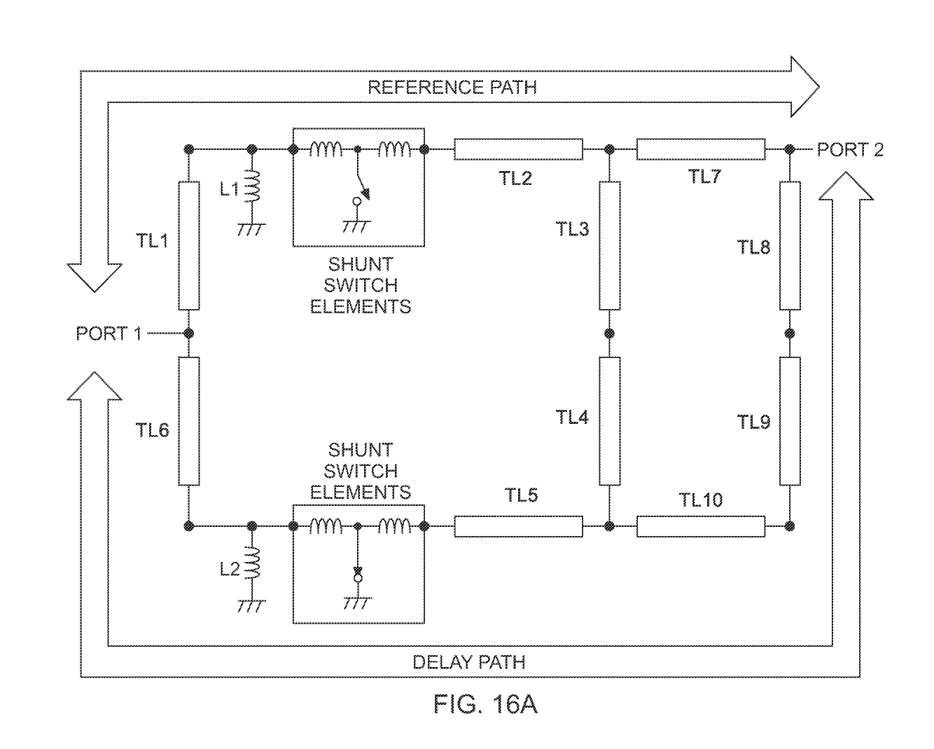

The predicted performance of the exemplary design of the ring hybrid phase shifter of FIG. 12A is shown in FIGS. 14-15. Here, the two-port shunt switch element model was used, with 175 fF capacitance, 1.5 ohms on-resistance, and 300 pH inductance on both ports. The impedances and lengths of the transmission lines were optimized as listed in Table 3. Note that the electrical lengths of TL1, TL2, TL5 and TL6 are shorter than one-quarter wavelength, to account for the electrical length of the two-port shunt switch element's series inductances Lp. The resonators L1, L2 have been created using high-impedance transmission lines, a familiar practice at microwave frequencies.

TABLE 3

| Line segment | Impedance (ohms) | Electrical length (degrees) |
|---|---|---|
| TL1 | 80 | 76 |
| TL2 | 82 | 76 |
| TL3 | 46 | 90 |
| TL4 | 58 | 90 |
| TL5 | 90 | 76 |
| TL6 | 68 | 76 |
| Resonators L1, L2 | 73 | 63 |

There are no exact values for all of the parameters that provides the best response, as different optimization functions can be used to weight different characteristics. In the example, 20 dB return loss, 0.1 dB amplitude flatness and +/−1 degree phase errors are predicted over 20% bandwidth (9 to 11 GHz).

A modification to the phase shifter in FIG. 12 is shown in FIG. 12B. Here the shunt inductors have been removed and replaced with shunt capacitors at the input and output ports, C1A and C1B. The capacitors values may be close in value to ½ of the off-capacitance of the shunt switch elements.

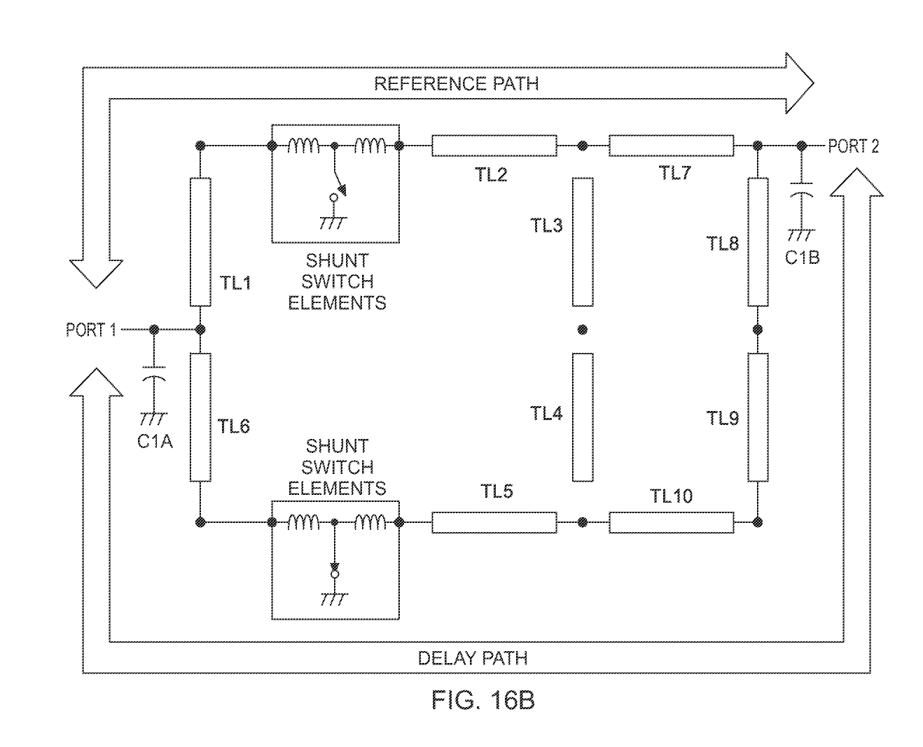

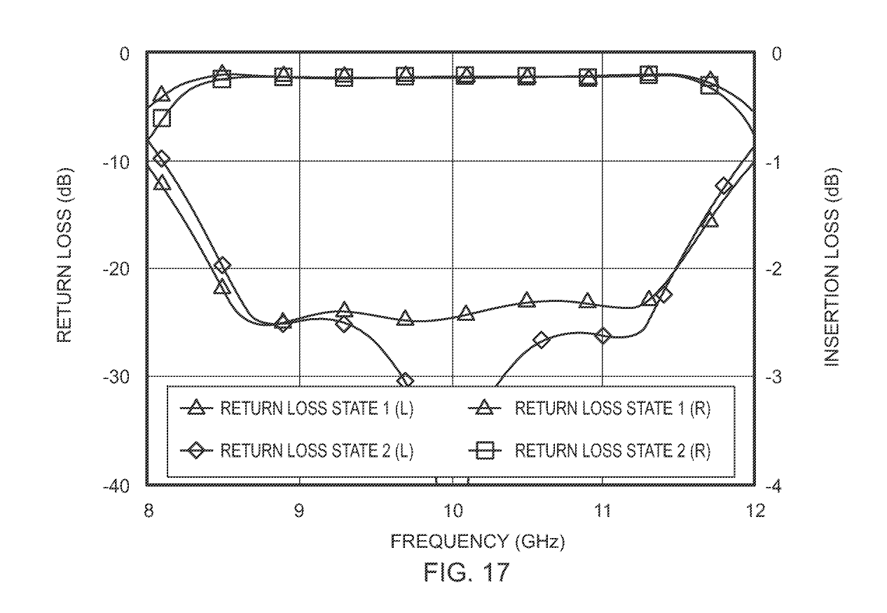

A second configuration of a ring hybrid phase shifter in accordance with the present invention is shown in FIG. 16A, having two rings and thus wider bandwidth than that of the phase shifter of FIG. 12A. There are two tradeoffs that must be considered when using this phase shifter: it is physically larger than the phase shifter of FIG. 12A, and it will have more RF loss. Using the same diode parameters as example of FIG. 12A, the network can be optimized to arrive at the impedance and electrical length values of Table 4.

TABLE 4

| Line segment | Impedance (ohms) | Electrical length (degrees) |
|---|---|---|
| TL1 | 69 | 77 |
| TL2 | 79 | 77 |
| TL3 | 58 | 90 |
| TL4 | 60 | 90 |
| TL5 | 83 | 77 |
| TL6 | 66 | 77 |
| TL7 | 90 | 90 |
| TL8 | 37 | 90 |
| TL9 | 26 | 90 |
| TL10 | 90 | 90 |
| Resonators L1, L2 | 90 | 62 |

A modification to the phase shifter in FIG. 16A is shown in FIG. 16B. Here the shunt inductors have been removed and replaced with shunt capacitors at the input and output ports, C1A and C1B. The capacitors values may be close in value to ½ of the off capacitance of the shunt switch elements.

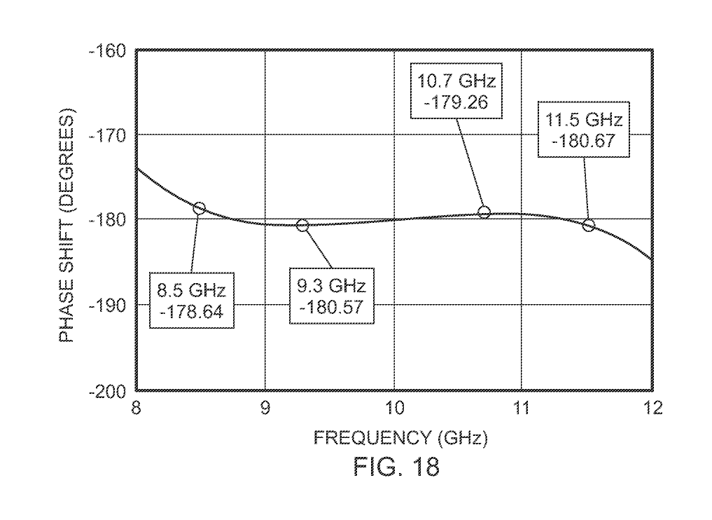

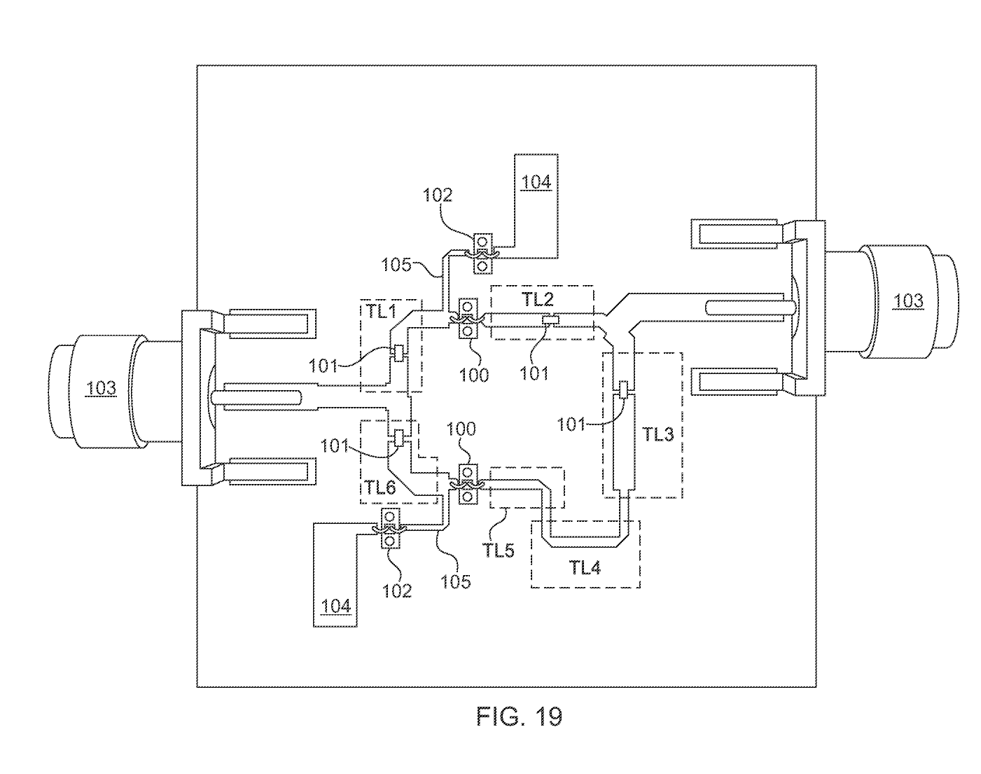

The predicted performance of the wideband network example in FIG. 16A is shown in FIGS. 17, 18. In the example, 20 dB return loss, 0.1 dB amplitude flatness and +/−1 degree phase errors are predicted over 30% bandwidth (8.5 to 11.5 GHz). Note that additional rings may be added to the network for more bandwidth, but with diminishing returns.

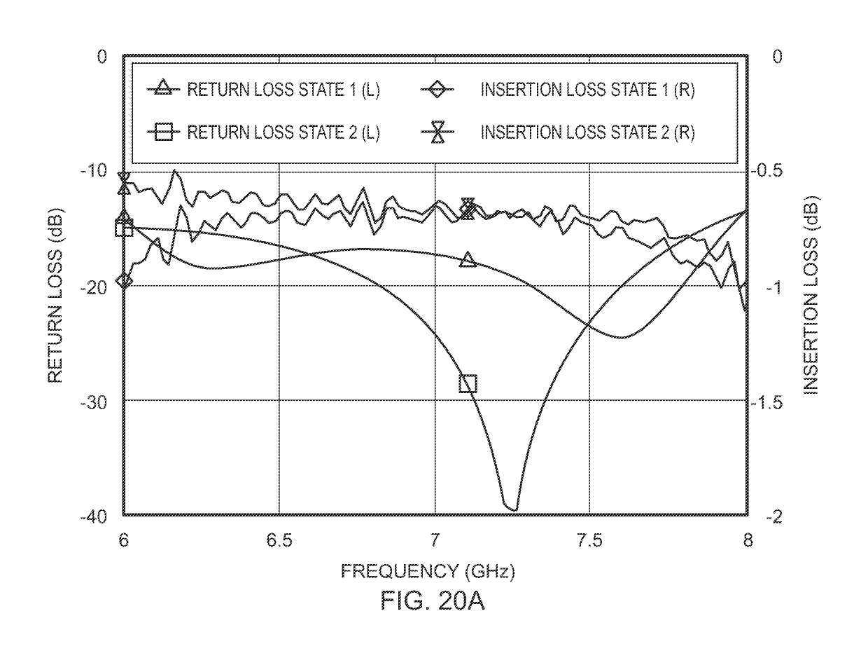

A physical implementation of the phase shifter of FIG. 12A is shown in FIG. 19. In this example, PIN diodes were used as switch elements 100. The circuit was designed for 7 GHz operation and is laid out on a board with dielectric constant 2.2 and substrate height of 508 microns and includes input/output couplers 103. The bias circuits for the PIN diodes 100 include blocking capacitors 101, bypass capacitors 102, bias stubs 105, and bias control signal inputs 104. In this example, the PIN diodes' off capacitance was approximately 0.175 fF and the on-resistance was ˜1 ohm. Wire-bonds of 400 μm length were absorbed into the design. Bias stubs 105 also act as resonant inductor to compensate for the parasitic capacitance of the diodes 100. Line widths and their corresponding impedances for the physical example of FIG. 19 are provided in Table 5. The electrical lengths cannot be accurately reported as a single number, owing to the effects of tee junctions on transmission phase.

TABLE 5

| Segment | Width (microns) | Impedance (ohms) |
|---|---|---|
| TL1 | 944 | 67 |
| TL2 | 728 | 77 |
| TL3 | 1175 | 59 |
| TL4 | 500 | 92 |
| TL5 | 500 | 92 |
| TL6 | 1270 | 56 |
| Resonators L1 and L2 (105) | 250 | 120 |

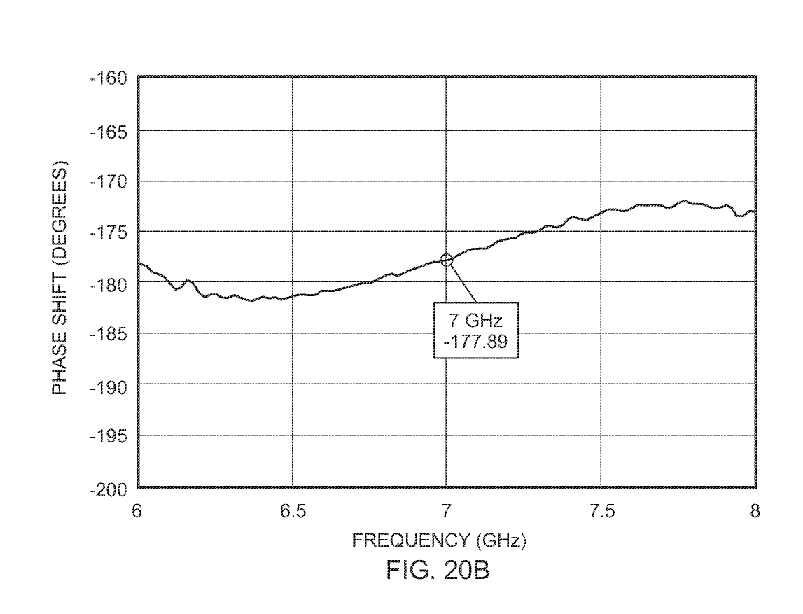

The measured performance of the prototype of FIG. 19 is shown in FIGS. 20A-20B. Its performance substantially achieves the design goals of 0.6 dB insertion loss and +/−5 degree phase errors, but with some slight degradation in return losses which can be corrected by applying rigorous electro-magnetic modeling and a minor redesign.

These and other advantages of the present invention will be apparent to those skilled in the art from the foregoing specification. Accordingly, it will be recognized by those skilled in the art that changes or modifications may be made to the above-described embodiments without departing from the broad inventive concepts of the invention. It should therefore be understood that this invention is not limited to the particular embodiments described herein, but is intended to include all changes and modifications that are within the scope and spirit of the invention as set forth in the claims. Furthermore, the transitional terms “comprising” and “consisting of” when used in the appended claims define the claim scope with respect to what unrecited additional claim elements or steps, if any, are excluded from the scope of the claims. The term “comprising” is intended to be inclusive or open-ended and does not exclude any additional unrecited element or material. The term “consisting of” excludes any element or material other than those used in connection therewith as specified in the claims.

What is claimed is:

1. A microwave digital phase shifter, comprising input and output ports having a reference path and a delay path disposed in parallel therebetween, the reference path including a switch element shunted to ground and the delay path including at least one switch element shunted to ground and including a transmission line to provide a phase difference between the reference path and the delay path.

2. The microwave digital phase shifter according to claim 1, wherein the switch elements of the reference and delay paths are FETs.

3. The microwave digital phase shifter according to claim 1, wherein the switch elements of the reference and delay paths are PIN diodes.

4. The microwave digital phase shifter according to claim 1, wherein the reference path includes a shunt resonator to provide a resonant structure in parallel with the capacitance of the switch element of the reference path.

5. The microwave digital phase shifter according to claim 4, wherein the shunt resonator comprises a high-impedance transmission line.

6. The microwave digital phase shifter according to claim 1, wherein the delay path includes shunt resonators to provide respective resonant structures in parallel with the capacitance of each of the at least one switch elements of the delay path.

7. The microwave digital phase shifter according to claim 6, wherein the shunt resonator comprises a high-impedance transmission line.

8. The microwave digital phase shifter according to claim 1, wherein the at least one switch elements of the delay path comprises two switch elements.

9. The microwave digital phase shifter according to claim 8, where the two switch elements are electrically coupled to one another to operate simultaneously.

10. The microwave digital phase shifter according to claim 1, comprising a capacitor shunted to ground at each of the input and output ports.

11. The microwave digital phase shifter according to claim 1, wherein the reference and delay paths are configured to consist of a ring hybrid phase shifter.

12. The microwave digital phase shifter according to claim 1, wherein the reference and delay paths are configured to comprise a ring hybrid phase shifter.

13. The microwave digital phase shifter according to claim 12, wherein the ring hybrid phase shifter comprises two rings.

14. The microwave digital phase shifter according to claim 12, wherein the ring hybrid phase shifter has an impedance that varies around the ring.

15. The microwave digital phase shifter according to claim 12, wherein the switch elements of the delay and reference paths are disposed within rings of the ring hybrid phase shifter.

16. The microwave digital phase shifter according to claim 1, wherein the reference and delay paths are configured to comprise two single pole, double throw switches arranged back-to-back with the input and output ports located at a respective one of the single poles.

17. The microwave digital phase shifter according to claim 1, wherein the reference and delay paths are configured to consist of two single pole, double throw switches arranged back-to-back with the input and output ports located at a respective one of the single poles.

18. The microwave digital phase shifter according to claim 1, wherein the delay and references paths consist of shunt elements and transmission lines configured to introduce a phase delay.
